(19) United States
(12) Patent Application Publication
(10) Pub. No.: US 2020/0235185 A1
(43) Pub. Date: Jul. 23, 2020

(54) AMOLED DISPLAY PANEL AND DISPLAY DEVICE

(71) Applicant: Shenzhen China Star Optoelectronics Semiconductor Display Technology Co., Ltd., Shenzhen, Guangdong (CN)

(72) Inventor: Chenglei NIE, Shenzhen, Guangdong (CN)

(73) Assignee: Shenzhen China Star Optoelectronics Semiconductor Display Technology Co., Ltd., Shenzhen, Guangdong (CN)

(21) Appl. No.: 15/757,348

(22) PCT Filed: Sep. 14, 2017
(86) PCT No.: PCT/CN2017/101769

§ 371 Date: Mar. 3, 2018

(30) Foreign Application Priority Data
Aug. 23, 2017 (CN) 201710731758.6

(51) Int. Cl. H01L 27/32; H01L 51/52; G09G 3/3233

(52) U.S. Cl. CPC H01L 27/3269; H01L 51/5234; G09G 3/3233; H01L 2251/5323; G09G 2320/045; G09G 2360/148; G09G 2300/0452; G09G 2360/142; G09G 2320/0233; H01L 27/3211

(57) ABSTRACT

The present disclosure discloses an AMOLED display panel, including a TFT array substrate and sub-pixels arranged in an array on the TFT array substrate, wherein each sub-pixel includes a first light-emitting region and a second light-emitting region which have a same emissive layer structure, one of the first light-emitting region and the second light-emitting region is a top light-emitting structure and the other is a bottom light-emitting structure; the first light-emitting region is for displaying an image, a light-detecting member is disposed on a light-emitting surface of the second light-emitting region, the light-detecting member is configured to detect a light-emitting luminance of the second light-emitting region to determine whether the sub-pixels need to perform brightness compensation and a corresponding brightness compensation value. The present disclosure also discloses a display device including a driving module and an AMOLED display panel as described above.

### RELATED APPLICATIONS

The present application is a National Phase of International Application Number PCT/CN2017/101769, filed Sep. 14, 2017, and claims the priority of China Application No. 201710731758.6, filed Aug. 23, 2017.

### FIELD OF THE DISCLOSURE

The present disclosure relates to a display device technology field, and more particularly to an AMOLED display panel and a display device.

### BACKGROUND OF THE DISCLOSURE

Organic light-emitting diodes (OLEDs) are self-luminous with a very thin layer of organic material and a glass substrate that shines when an electric current is passed through. In addition, the organic light-emitting diode display screen has a large viewing angle and can save energy significantly. Therefore, organic light-emitting diodes are used more and more widely.

The core component of the OLED display device is an OLED display panel, the structure of the OLED display panel generally includes a TFT array substrate and an anode layer, a pixel defining layer, a first common layer for transporting holes, an emissive layer, a second common layer for transporting electrons, and a cathode layer sequentially formed on the TFT substrate. The working principle of the OLED display panel is that under the action of an electric field between the anode and the cathode, holes are transmitted to the emissive layer through the first common layer, electrons are transmitted to the emissive layer through the second common layer, and holes and electrons recombine in the emissive layer to emit light.

The OLED display device can be divided into two categories of passive matrix OLED (PMOLED) and active matrix OLED (AMOLED) according to the driving mode, namely direct addressing and thin film transistor matrix addressing. Wherein AMOLED has a matrix arrangement of pixels, belonging to the active display type, high luminous efficiency, usually used for high-definition large-size display device. AMOLED is a current-driven device. When some current flows through the organic light-emitting diode, the organic light-emitting diode emits light, and the light-emitting brightness is determined by the current flowing through the organic light-emitting diode itself. Most of the existing integrated circuits only transmit voltage signals, so AMOLED's pixel driving circuit needs to complete the task of converting voltage signals into current signals.

Conventional AMOLED pixel driver circuit is usually 2T1C, that is, two thin-film transistors plus a capacitor structure, the voltage is converted to current. One of the thin film transistors is a switching thin film transistor for controlling data signal access, the other thin film transistor is a driving thin film transistor for controlling the current flowing through the organic light-emitting diode. Therefore, the threshold voltage driving the thin film transistor is very important. Both the positive and negative threshold voltages can cause different currents to pass through the organic light emitting-diode under the same data signal.

In addition, because the AMOLED utilizes the current through the thin film of organic material to generate light, different organic materials emit light of different colors. With the use of AMOLEDs, the organic materials in the device age, while the luminous efficiency will be lower, reducing the life of the display device. Different organic materials can age at different speeds, leading to different degrees of color aging, and the display's white field varies with the use of the display. In addition, individual pixels may age at a different rate than other pixels, resulting in non-uniform display. Therefore, AMOLED display devices must have compensation to maintain their performance.

### SUMMARY OF THE DISCLOSURE

In view of this, the present disclosure provides an AMOLED display panel to solve the problem of brightness compensation of an AMOLED display panel.

In order to achieve the above object, the present disclosure adopts the following technical solutions:

An AMOLED display panel, including a TFT array substrate and sub-pixels arranged in an array on the TFT array substrate, wherein each sub-pixel includes a first light-emitting region and a second light-emitting region which have a same emissive layer structure, one of the first light-emitting region and the second light-emitting region is a top light-emitting structure and the other is a bottom light-emitting structure; the first light-emitting region is for displaying an image, a light-detecting member is disposed on a light-emitting surface of the second light-emitting region, the light-detecting member is configured to detect a light-emitting luminance of the second light-emitting region to determine whether the sub-pixels need to perform brightness compensation and a corresponding brightness compensation value.

Wherein the TFT array substrate includes a pixel circuit region and a light-transmitting region outside the pixel circuit region, the first light-emitting region is a top light-emitting structure and correspondingly disposed above the pixel circuit region; the second light-emitting region is a bottom light-emitting structure and is correspondingly disposed above the light-transmitting region.

Wherein each sub-pixel includes an anode, an organic light-emitting layer and a cathode sequentially disposed on the TFT array substrate; wherein the first light-emitting region and the second light-emitting region share the same anode and the organic light-emitting layer, the cathode of the first light-emitting region is a transparent cathode, and the cathode of the second light-emitting region is an opaque cathode.

Wherein the light-detecting member is disposed on a surface of the TFT array substrate facing away from the sub-pixel.

Wherein each sub-pixel is correspondingly provided with one of the light-detecting members.

Wherein the adjacent multiple sub-pixels are correspondingly provided with one common light-detecting member.

Wherein the light-detecting member is a photodiode.

Wherein the sub-pixels arranged in an array on the TFT array substrate include a red sub-pixel, a green sub-pixel and a blue sub-pixel.

The present disclosure also provides a display device including a driving module and an AMOLED display panel as described above, the driving module including: a comparison unit for comparing the brightness signal value detected by the light-detecting member with a preset standard brightness signal value to determine whether brightness compensation needs to be performed with a corresponding compensation value;

a receiving unit for receiving an image data signal to be displayed;
a compensation unit for performing brightness compensation on the image data signal according to the compensation value determined by the comparison unit, so as to match the brightness signal value detected by the light-detecting member and the preset standard brightness signal value; and
an output unit for outputting a compensated image data signal to the AMOLED display panel to drive the AMOLED display panel to display an image.

Compared with the prior art, in the AMOLED display panel and the corresponding display device provided in the embodiments of the present disclosure, a top-emitting structure region and a bottom-emitting structure region are disposed in one sub-pixel. In a specific embodiment, the top light-emitting structure region is used for displaying an image, and the bottom light-emitting structure region is used to detect light emitting brightness. If the luminescence brightness detected from the bottom-emitting structure region does not match the standard value, it indicates that the luminescence for displaying the top-emitting structure region of the screen is abnormal. In this case, the driving signal is compensated so that the light emission of the top-emitting structure region is restored to the standard brightness requirement, which can well improve the display quality of the display panel.

### BRIEF DESCRIPTION OF THE DRAWINGS

FIG. 1 is a schematic structural diagram of an AMOLED display panel provided by an embodiment of the present disclosure.

FIG. 2 is a schematic structural diagram of a pixel unit in an embodiment of the present disclosure.

FIG. 3 is a schematic structural diagram of a pixel unit in a preferred embodiment of the present disclosure

FIG. 4 is a schematic structural diagram of a display device according to an embodiment of the present disclosure.

### DETAILED DESCRIPTION OF PREFERRED EMBODIMENTS

To make the objectives, technical solutions, and advantages of the present disclosure clearer, the following describes the specific implementation manners of the present disclosure in detail with reference to the accompanying drawings. Examples of these preferred embodiments are illustrated in the drawings. The embodiments of the present disclosure shown in the drawings and described in the drawings are merely exemplary and the present disclosure is not limited to these embodiments.

It should also be noted that in order to avoid obscuring the disclosure with unnecessary detail, only the structures and/or processing steps which are closely related to the solution according to the disclosure are shown in the drawings, while omitting other details that have little to do with the present disclosure.

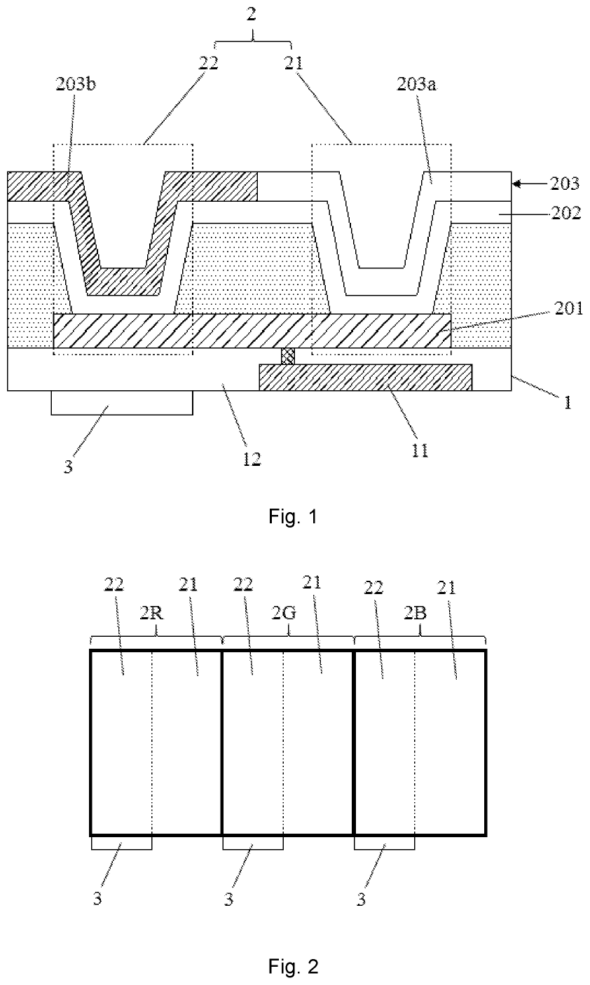

The present embodiment firstly provides an AMOLED display panel, as shown in FIG. 1, including a TFT array substrate 1 and sub-pixels 2 arranged in an array arranged on the TFT array substrate 1. It should be noted that only one of the sub-pixels 2 is illustrated in the drawings by way of example.

Each sub-pixel 2 includes a first light-emitting region 21 and a second light-emitting region 22 having the same structure of emissive layers, one of the first light-emitting region 21 and the second light-emitting region 22 is a top light-emitting structure and the other is a bottom light-emitting structure. Here, the same structure of the emissive layers means that the material of the emissive layer is the same in the first light-emitting region 21 and the second light-emitting region 22, and the manufacturing process of the emissive layer is also the same, and the first light-emitting region 21 and the second light-emitting region 22 share the same pixel driving circuit.

The first light-emitting region 21 is for displaying a screen, and a light-detecting member 3 is disposed on a light-exiting surface of the second light-emitting region 22. The light-detecting member 3 is configured to detect the light emitting brightness of the second light-emitting region 22 to determine whether the sub-pixel 2 needs to perform brightness compensation and a corresponding brightness compensation value.

The light emission luminance of the second light-emitting region 22 is detected by the light-detecting member 3, the detected value is compared with the standard value. If the detected value does not match the preset standard value, it indicates that the corresponding emissive layer in the first light-emitting region 21 and the second light-emitting region 22 is aged or the voltage of the thin-film transistor in the corresponding pixel driving circuit is drifted. In this case, the driving signal of the display panel needs to be compensated until the light emitting brightness detected by the light-detecting member 3 matches the preset standard value, so as to improve the display quality of the display panel. The standard value of the light emitting brightness of the second light-emitting region 22 may be the light emitting brightness of the second light-emitting region 22 when the display panel is shipped from the factory.

Specifically, as shown in FIG. 1, in the present embodiment, the first light-emitting region 21 is a top light emitting structure, and the second light-emitting region 22 is a bottom light emitting structure. The TFT array substrate 1 includes a pixel circuit region 11 and a light-transmitting region 12 outside the pixel circuit region 11. The first light-emitting region 21 is correspondingly disposed above the pixel circuit region 11, the second light-emitting region 22 is correspondingly disposed above the light-transmitting region 12. Further, each sub-pixel 2 includes an anode 201, an organic light-emitting layer 202 and a cathode 203 sequentially disposed on the TFT array substrate 1, the first light-emitting region 21 and the second light-emitting region 22 share the same anode 201 and the organic light-emitting layer 202, the cathode 203a of the first light-emitting region 21 is a transparent cathode, and the cathode of the second light-emitting region 22 is an opaque cathode 203b. The anode 201 is electrically connected to the pixel circuit region 11 in the TFT array substrate 1. That is, the first light-emitting region 21 and the second light-emitting region 22 share the same pixel driving circuit.

In general, the organic light-emitting layer 202 includes a first common layer for transporting holes, an emissive layer (EML) and a second common layer for transporting electrons sequentially disposed on the anode 201. The first common layer includes a hole injection layer (HIL) and a hole transport layer (HTL) sequentially disposed in a direction gradually away from the anode 201, and an electron blocking layer may be further disposed thereon. The second common layer includes an electron injection layer (EIL) and an electron transport layer (ETL) sequentially disposed in a direction away from the cathode 203, and a hole blocking layer may be further disposed.

The light-detecting member 3 is disposed on the surface of the TFT array substrate 1 on a side away from the sub-pixel 2, and the light-detecting member 3 may be selected as a photodiode. Specifically, in the present embodiment, referring to FIG. 1 and FIG. 2, the sub-pixels 2 arranged in an array on the TFT array substrate 1 include a red sub-pixel 2R, a green sub-pixel 2G and a blue sub-pixel 2B. The red sub-pixel 2R, the green sub-pixel 2G and the blue sub-pixel 2B arranged in sequence constitute one-pixel unit. Each of the red sub-pixel 2R, the green sub-pixel 2G and the blue sub-pixel 2B includes a first light-emitting region 21 and a second light-emitting region 22, respectively. Each sub-pixel 2R, 2G, and 2B is correspondingly provided with one of the light-detecting members 3. That is, each of the light-detecting members 3 is only used to detect the light-emitting luminance of the second light-emitting region 22 in one of the sub-pixels 2.

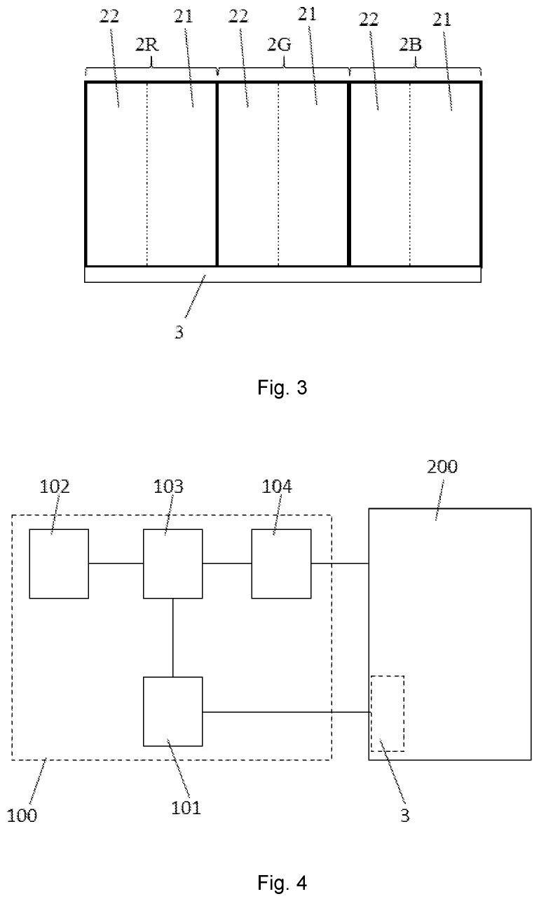

In another embodiment, it may also be configured that the adjacent multiple sub-pixels 2 are correspondingly provided with one common light-detecting member 3, that is, one light-detecting member 3 is used to detect the light emission luminance of the second light-emitting region 22 in the adjacent plurality of sub-pixels 2. As an example, as shown in FIG. 3, the red sub-pixel 2R, the green sub-pixel 2G and the blue sub-pixel 2B in one-pixel unit are correspondingly provided with one light-detecting member 3, the light-detecting member 3 is configured to detect the light-emitting luminance of the second light-emitting regions 22 of the red sub-pixel 2R, the green sub-pixel 2G and the blue sub-pixel 2B in one-pixel unit.

The present embodiment further provides a display device. As shown in FIG. 4, the display device includes a driving module 100 and a display panel 200. The driving module 100 provides a driving signal to the display panel 200 to make the display panel 200 display an image.

Wherein, the display panel 200 adopts the AMOLED display panel provided in the above embodiment of the present disclosure.

As shown in FIG. 4, the driving module 100 includes a comparison unit 101, a receiving unit 102, a compensation unit 103, and an output unit 104.

The comparison unit 101 is electrically connected to the light-detecting member 3 in the AMOLED display panel 200. The comparison unit 101 stores a preset standard brightness signal value, the comparison unit 101 is configured to compare the brightness signal value detected by the light-detecting member 3 with a preset standard brightness signal value to determine whether brightness compensation needs to be performed with a corresponding compensation value.

The receiving unit 102 is configured to receive an image data signal to be displayed.

The compensation unit 103 is connected to the comparison unit 101, the receiving unit 102 and the output unit 104, respectively. The receiving unit 102 sends the received image data signal to the compensation unit 103, and the comparing unit 101 sends the signal compensation value to the compensation unit 103, the compensation unit 103 compensates the image data signal according to the signal compensation value determined by the comparison unit 101, and then sends the compensated image data signal to the output unit 104.

The output unit 104 outputs the compensated image data signal to the AMOLED display panel 200 to drive the AMOLED display panel 200 to display an image.

The brightness compensation method of the display device as described above can be performed according to the following steps:

S1, providing the receiving unit 102 with an image data signal of a test image, outputting the image data signal to the AMOLED display panel 200 by the output unit 104, and driving the AMOLED display panel 200 to display an image.

S2, detecting the light emission brightness of the second light-emitting region 22 in the AMOLED display panel 200 by the light-detecting member 3 when displaying the test image.

S3, comparing the brightness signal value detected by the light-detecting member 3 with a preset standard brightness signal value by the comparison unit 101: if the test value does not match with the standard value, then the need for brightness compensation and determine the appropriate compensation value, the size of the compensation value is the difference between the test value and the standard value; if the detection value is consistent with the standard value, it means that no brightness compensation is needed or the brightness compensation value is 0. The standard brightness signal value refers to a pre-stored standard brightness signal corresponding to the test image. For example, when the display panel is shipped from the factory. When the input data signal is the data signal of the test image, the light-emitting luminance signal corresponding to the second light-emitting region 22 at this time.

S4, providing the receiving unit 102 with an image data signal to be displayed, the compensation unit 103 compensates the image data signal according to the signal compensation value determined by the comparison unit 101 and then outputs the compensated image data signal to the display panel 200.

It should be noted that, as the use of time increases, the degree of brightness attenuation may be more and more. Therefore, in the above display apparatus and its brightness compensation method, the brightness of the test image may be periodically checked so that the brightness compensation value determined by the comparison unit can be adapted to the current degree of brightness attenuation.

In summary, in the AMOLED display panel and the corresponding display device provided in the embodiments of the present disclosure, a top light-emitting structure region and a bottom light-emitting structure region are disposed in one sub-pixel. In a specific embodiment, the top light-emitting structure region is used for displaying an image, and the bottom light-emitting structure region is used to detect light emitting brightness. If the luminescence brightness detected from the bottom light-emitting structure region does not match the standard value, it indicates that the luminescence for displaying the top light-emitting structure region of the screen is abnormal. In this case, the driving signal is compensated so that the light emission of the top light-emitting structure region is restored to the standard brightness requirement, which can well improve the display quality of the display panel.

It should be noted that, in this article, relational terms, such as first and second, and the like, are only used to distinguish one entity or operation from another. Without necessarily requiring or implying any actual relationship or order between such entities or operations. Moreover, the terms “including,” “comprising,” or any other variation thereof, are intended to cover a non-exclusive inclusion such that a process, method, article, or apparatus that includes a list of elements includes not only those elements, but also include other elements not expressly listed or also include elements inherent to the process, method, article, or device. Without further limitations, an element limited by the statement “including a . . . ” does not exclude the existence of additional identical elements in the process, method, article, or apparatus that includes the element.

The foregoing descriptions are merely specific implementation manners of the present application. It should be noted that those skilled in the art may make various improvements and modifications without departing from the principle of the present application, and these improvements and modifications should also be considered as falling within the protection scope of the present application.

What is claimed is:

1. An AMOLED display panel, comprising a TFT array substrate and sub-pixels arranged in an array on the TFT array substrate, wherein each sub-pixel comprises a first light-emitting region and a second light-emitting region which have a same emissive layer structure, one of the first light-emitting region and the second light-emitting region is a top light-emitting structure and the other is a bottom light-emitting structure; the first light-emitting region is for displaying an image, a light-detecting member is disposed on a light-emitting surface of the second light-emitting region, the light-detecting member is configured to detect a light-emitting luminance of the second light-emitting region to determine whether the sub-pixels need to perform brightness compensation and a corresponding brightness compensation value.

2. The AMOLED display panel according to claim 1, wherein the TFT array substrate comprises a pixel circuit region and a light-transmitting region outside the pixel circuit region, the first light-emitting region is a top light-emitting structure and correspondingly disposed above the pixel circuit region; the second light-emitting region is a bottom light-emitting structure and is correspondingly disposed above the light-transmitting region.

3. The AMOLED display panel according to claim 2, wherein each sub-pixel comprises an anode, an organic light-emitting layer and a cathode sequentially disposed on the TFT array substrate; wherein the first light-emitting region and the second light-emitting region share the same anode and the organic light-emitting layer, the cathode of the first light-emitting region is a transparent cathode, and the cathode of the second light-emitting region is an opaque cathode.

4. The AMOLED display panel according to claim 2, wherein the light-detecting member is disposed on a surface of the TFT array substrate facing away from the sub-pixel.

5. The AMOLED display panel according to claim 1, wherein each sub-pixel is correspondingly provided with one of the light-detecting members.

6. The AMOLED display panel according to claim 5, wherein the light-detecting member is a photodiode.

7. The AMOLED display panel according to claim 1, wherein the adjacent multiple sub-pixels are correspondingly provided with one common light-detecting member.

8. The AMOLED display panel according to claim 7, wherein the light-detecting member is a photodiode.

9. The AMOLED display panel according to claim 1, wherein the sub-pixels arranged in an array on the TFT array substrate comprise a red sub-pixel, a green sub-pixel and a blue sub-pixel.

10. A display device, comprising a driving module and an AMOLED display panel, wherein the AMOLED display panel comprises a TFT array substrate and sub-pixels arranged in an array on the TFT array substrate, wherein each sub-pixel comprises a first light-emitting region and a second light-emitting region which have a same emissive layer structure, one of the first light-emitting region and the second light-emitting region is a top light-emitting structure and the other is a bottom light-emitting structure; the first light-emitting region is for displaying an image, a light-detecting member is disposed on a light-emitting surface of the second light-emitting region, the light-detecting member is configured to detect a light-emitting luminance of the second light-emitting region to determine whether the sub-pixels need to perform brightness compensation and a corresponding brightness compensation value; wherein the driving module comprises:
a comparison unit for comparing the brightness signal value detected by the light-detecting member with a preset standard brightness signal value to determine whether brightness compensation needs to be performed with a corresponding compensation value;
a receiving unit for receiving an image data signal to be displayed;
a compensation unit for performing brightness compensation on the image data signal according to the compensation value determined by the comparison unit, so as to match the brightness signal value detected by the light-detecting member and the preset standard brightness signal value; and
an output unit for outputting a compensated image data signal to the AMOLED display panel to drive the AMOLED display panel to display an image.

11. The display device according to claim 10, wherein the TFT array substrate comprises a pixel circuit region and a light-transmitting region outside the pixel circuit region, the first light-emitting region is a top light-emitting structure and correspondingly disposed above the pixel circuit region; the second light-emitting region is a bottom light-emitting structure and is correspondingly disposed above the light-transmitting region.

12. The display device according to claim 11, wherein each sub-pixel comprises an anode, an organic light-emitting layer and a cathode sequentially disposed on the TFT array substrate; wherein the first light-emitting region and the second light-emitting region share the same anode and the organic light-emitting layer, the cathode of the first light-emitting region is a transparent cathode, and the cathode of the second light-emitting region is an opaque cathode.

13. The display device according to claim 11, wherein the light-detecting member is disposed on a surface of the TFT array substrate facing away from the sub-pixel.

14. The display device according to claim 10, wherein each sub-pixel is correspondingly provided with one of the light-detecting members.

15. The display device according to claim 14, wherein the light-detecting member is a photodiode.

16. The display device according to claim 10, wherein the adjacent multiple sub-pixels are correspondingly provided with one common light-detecting member.

17. The display device according to claim 16, wherein the light-detecting member is a photodiode.

18. The display device according to claim 10, wherein the sub-pixels arranged in an array on the TFT array substrate comprise a red sub-pixel, a green sub-pixel and a blue sub-pixel.
